(19) United States
(12) Patent Application Publication
(10) Pub. No.: US 2010/0248476 A1
(43) Pub. Date: Sep. 30, 2010

(54) METHOD OF MANUFACTURING SEMICONDUCTOR DEVICE

(75) Inventors: Yuji Sera, Tokyo (JP); Kazuhiro Okuda, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/728,501

(22) Filed: Mar. 22, 2010

(30) Foreign Application Priority Data
Mar. 24, 2009 (JP) P2009-072265

(51) Int. Cl. H01L 21/3205

(52) U.S. Cl. 438/669; 257/E21.295

(57) ABSTRACT

A method of manufacturing a semiconductor device may include, but is not limited to, the following processes. A conductive film is formed over a semiconductor substrate. First and second photo resist patterns are formed on the conductive film. A space is located between the first and second photo resist patterns. An insulating mask is formed by using catalytic reaction so as to cover surfaces of the first and second photo resist patterns. The insulating mask protects the surfaces of the first and second photo resist patterns. A part of the conductive film is etched by using the insulating mask on the first and second photo resist patterns as an etching mask.

### BACKGROUND OF THE INVENTION

1. Field of the Invention

The present invention relates to a method of manufacturing a semiconductor device.

Priority is claimed on Japanese Patent Application No. 2009-072265, filed Mar. 24, 2009, the content of which is incorporated herein by reference.

2. Description of the Related Art

Recently, advances in integration have been demanded for further miniaturized and thinner semiconductor devices. Additionally, regarding a process of manufacturing a miniaturized semiconductor device, etching using a hard mask made of an insulating film, such as a silicon oxide film (SiO₂), has been generally used, in lieu of etching using a pattern made of photo resist films as a mask, for processing a metal wiring layer or the like used as an element. This is effective when the etching resistance of the photo resist film is not sufficient at the time of dry etching.

When a hard mask is formed in one of the semiconductor-device manufacturing processes, a process of depositing a hard mask material, a process of patterning the hard mask material by dry etching, and the like are required, thereby increasing the number of processes.

Additionally, it is required to transfer, by etching, the pattern made of the photo resist films onto the hard mask layer and then carry out etching again to form the pattern of the metal wiring layer. For this reason, the final size of the metal wiring layer is likely to vary.

This is because an amount of side etching generally varies depending on a position on a surface of a semiconductor substrate due to the effects of an adjacent pattern and the like, thereby affecting the size of the metal wiring layer.

To solve the above problem, Japanese Patent Laid-Open Publication No. 2002-107957 discloses a technique of reforming a surface layer of a pattern made of silicon-containing photo resist films into silicon oxide films, and then using the silicon oxide films as hard masks.

However, it is difficult to form a miniaturized pattern since a resolution degrades by silicon being added to the photo resist films. Since only the thin surface layer of the photo resist films is reformed into the silicon oxide films, the etching resistance of the silicon oxide films as hard masks is insufficient.

Japanese Patent Laid-Open Publication No. 2004-40110 discloses a technique of forming, by CVD (Chemical Vapor Deposition), a thin film made of a silicon oxide film using a catalytic reaction when an insulating hard mask is formed over a semiconductor substrate. However, the number of processes increases if the above method is applied to the formation of the hard masks, thereby causing high manufacturing costs.

### SUMMARY

In one embodiment, a method of manufacturing a semiconductor device may include, but is not limited to, the following processes. A conductive film is formed over a semiconductor substrate. First and second photo resist patterns are formed on the conductive film. A space is located between the first and second photo resist patterns. An insulating mask is formed by using catalytic reaction so as to cover surfaces of the first and second photo resist patterns. The insulating mask protects the surfaces of the first and second photo resist patterns. A part of the conductive film is etched by using the insulating mask on the first and second photo resist patterns as an etching mask.

In another embodiment, a method of manufacturing a semiconductor device may include, but is not limited to, the following processes. A conductive film is formed over a semiconductor substrate. First and second photo resist patterns are formed on the conductive film. A first gas including a catalytic material is provided over the semiconductor substrate. An attachment rate of the catalytic material to the first and second photo resist patterns is greater than that of the catalytic material to the conductive film. A second gas is provided so that the second gas reacts with the catalytic material attached onto the first and second photo resist patterns to form an insulating hard mask covering surfaces of the first and second photo resist patterns. A part of the conductive film is etched by using the insulating mask on the first and second photo resist patterns as an etching mask.

In still another embodiment, a method of manufacturing a semiconductor device may include, but is not limited to, the following processes. A conductive film is formed over a semiconductor substrate. First and second photo resist patterns are formed on the conductive film. An insulating mask is formed using catalytic reaction so as to cover surfaces of the first and second photo resist patterns. A horizontal size of the conductive film exposed between the first and second photo resist patterns is reduced by formation of the insulating mask. The horizontal size is smaller than a resolution limit for forming the first and second photo resist patterns. A part of the conductive film is etched by using the insulating mask on the first and second photo resist patterns as an etching mask.

Accordingly, a miniaturized hard mask can be easily formed without increasing the number of processes. Therefore, a further miniaturized wiring pattern can be formed without increasing a variation in size of the wiring pattern.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a semiconductor device according to a first embodiment of the present invention;

FIGS. 2 to 5 are cross-sectional views indicative of a process flow illustrating a method of manufacturing the semiconductor device according to the first embodiment;

FIG. 6 illustrates one cycle of a hard mask formation process included in the method according to the first embodiment; and

FIGS. 7 to 9 are cross-sectional views indicative of a process flow illustrating a method of manufacturing the semiconductor device according to a second embodiment of the present invention.

### DETAILED DESCRIPTION OF THE PREFERRED EMBODIMENTS

The present invention will now be described herein with reference to illustrative embodiments. The accompanying drawings explain a method of manufacturing a semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

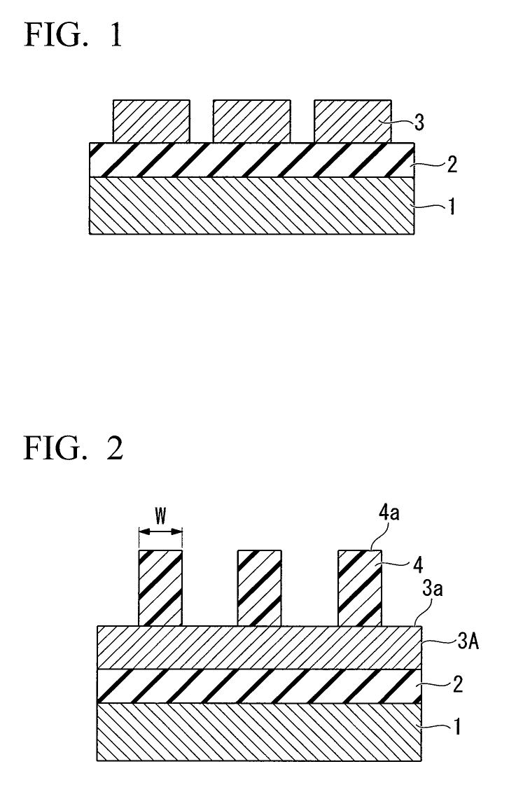

FIG. 1 is a cross-sectional view illustrating a method of manufacturing a semiconductor device A according to a first embodiment of the present invention. FIGS. 2 to 5 are cross-sectional views indicative of a process flow illustrating a method of manufacturing the semiconductor device A according to the first embodiment.

According to the method, at least an inter-layer insulating film 2 and a metal wiring layer 3 are formed over a semiconductor substrate 1 in this order. The metal wiring layer 3 is formed as follows. A pattern made of photo resist films 4 is formed on a metal film 3A formed over the inter-layer insulating film 2. Then, an insulator is selectively deposited on a surface 4a of each photo resist films 4 using a catalytic reaction to form an insulating hard mask 5 covering the photo resist film 4. Then, the metal film 3A is etched using the insulating hard masks 5.

The method of the first embodiment includes a process of forming the inter-layer insulating film 2 over the semiconductor substrate 1, and a process of forming the metal wiring layer 3 over the inter-layer insulating film 2, in this order. The process of forming the meal wiring layer 3 includes at least a resist formation process, a hard-mask formation process, and an etching process.

In the resist formation process, the metal film 3A is formed over the inter-layer insulating film 2, and then a pattern made of the photo resist films 4 is formed on the metal film 3A. In the hard-mask formation process, a catalytic gas 51 is provided onto the metal film 3A and the surface 4a of each photo resist film 4 to have a thin catalytic film 5A selectively absorb onto the surface 4a of each photo resist film 4. Then, a film forming gas 52 is provided to cause a catalytic reaction on the thin catalytic film 5A, and thus an insulator is selectively deposited on the surface 4a of each photo resist film 4 to form the insulating hard mask 5 covering the photo resist film 4. In the etching process, the metal film 3A is dry-etched using the insulating hard masks 5.

Hereinafter, the method of the first embodiment is specifically explained as a case where the metal wiring layer 5 is formed using a thin catalytic film, such as a tungsten film.

As shown in FIG. 1, the semiconductor device A manufactured by the method of the first embodiment includes the inter-layer insulating film 2 over the semiconductor substrate 1, and the metal wiring layer 3 on the inter-layer insulating film 2, the metal wiring layer 3 having a predetermined wiring pattern.

FIG. 1 shows the structure of the semiconductor device A in a state before other layers forming the semiconductor device, such as a protection film, bonding pads, and the like, are formed.

The semiconductor substrate 1 is made of silicon or the like. The inter-layer insulating film 2 made of a silicon oxide film (SiO₂) or the like is deposited over the semiconductor substrate 1. The metal wiring layer 3 is deposited on the inter-layer insulating film 2.

For example, the aforementioned tungsten, a known metal material (such as WSi, WN, Ti, TiN, or Al) used for a conventional semiconductor device, or a multi-layered film including multiple metal materials may be used for the metal wiring layer 3 without any limit.

Hereinafter, an example of the method of the first embodiment is explained with reference to FIGS. 2 to 5. As shown in FIG. 2, an insulating material, such as SiO₂, is deposited over the semiconductor substrate 1 to form the inter-layer insulating film 2. Then, a thin catalytic film made of tungsten or the like is deposited over the inter-layer insulating film 2 to form the metal film 3A.

In this case, known methods, such as spattering or CVD, may be used to form the inter-layer insulating film 2 and the metal film 3A. Although tungsten is used as a material forming the metal film 3A (metal wiring layer 3), another material, such as titanium nitride (TiN), may be appropriately used.

Then, in the resist formation process, a desired wiring pattern made of the photo resist films 4 is formed on the metal film 3A, as shown in FIG. 2. Specifically, the photo resist films 4 are formed such that a pattern width W between each of the photo resist films 4 is smaller by a predetermined value than a width of the final metal wiring layer 3 (see FIG. 1). In the case of FIG. 2, the pattern width W is smaller by 2T (T is a value of a thickness of the insulating hard mask 5 as will be explained) than the horizontal width of the metal wiring layer 3.

To make the pattern width W smaller than the width of the metal wiring layer 3, a wiring pattern on a photo mask (not shown) used for patterning the photo resist film 4 is preliminarily made thinner. Alternatively, an exposure condition for exposure of the photo resist film 4 is adjusted. A material for forming the photo resist film 4 is not limited to a specific material, and a known resist material may be used without any limit.

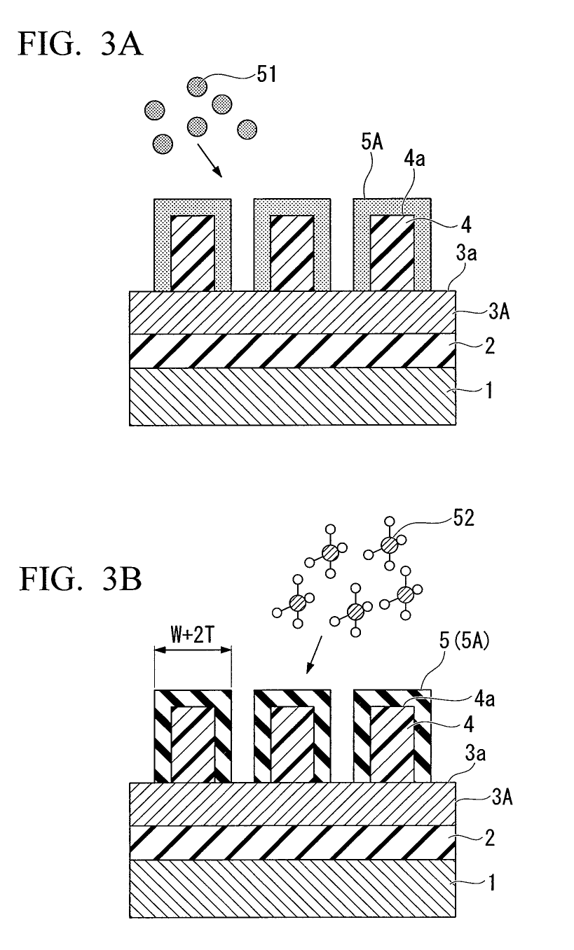

Then, in the hard-mask formation process, the insulating hard mask 5 is formed by CVD so as to selectively cover each of the photo resist films 4 forming the pattern, as shown in FIGS. 3A and 3B.

Specifically, the catalytic gas 51 is provided over the metal film 3A and the surfaces 4a of the photo resist films 4 to selectively deposit the thin catalytic film 5A on the surface 4a of each photo resist film 4. In the first embodiment, tri-methyl aluminum (hereinafter, “TMA”) is used as the catalytic gas 51 to selectively deposit the thin catalytic film 5A made of methyl aluminum on each photo resist film 4.

Then, the film forming gas 52 is provided on the thin catalytic film 5A to cause a catalytic reaction on the thin catalytic film 5A, and thus to form the insulating hard mask 5 as shown in FIG. 3B. In the first embodiment, tris (tert-pentoxy) silanol (hereinafter, “TPOS”) is used as the film forming gas 52 to cause a catalytic reaction of TPOS molecules on the thin catalytic film 5A made of methyl aluminum.

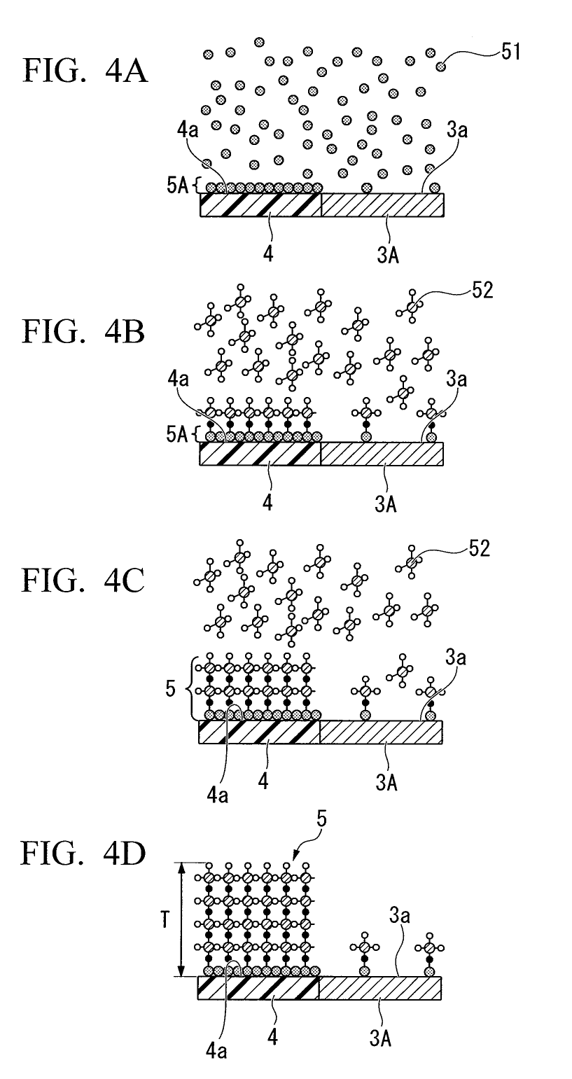

Hereinafter, the hard-mask formation process is specifically explained with reference to FIGS. 4A to 4D illustrating a principle of selectively forming the insulating hard mask 5 on the surface 4a of each photo resist film 4.

A semiconductor wafer including the semiconductor substrate 1, the inter-layer insulating film 2 and the metal film 3A over the semiconductor substrate 1, and the photo resist film 4 on the metal film 3A, as shown in FIG. 2, is introduced into a chamber included in a film forming apparatus (not shown).

Then, as a first step, TMA used as the catalytic gas 51 is provided into the chamber as shown in FIG. 4A. The inventor of the present invention found that the attachment rate of TMA molecules forming the catalytic gas 51 greatly varies depending on the material of a subject onto which the TMA molecules are attached.

Specifically, TMA molecules (catalytic gas 51) easily attach onto the surface 4a of the photo resist film 4, and therefore the surface 4a is covered by methyl aluminum (thin catalytic film 5A). On the other hand, TMA molecules hardly attach onto the surface of the metal film 3A. This is because the degree of chemical absorption of TMA molecules is determined depending on a termination state of the surface of the photo resist film 4 or the metal film 3A. The termination state is unique to each material forming the photo resist film 4 or the metal film 3A.

Then, the catalytic gas 51 made of TMA is released from the chamber. Then, as the second step, TPOS used as the film forming gas 52 is provided into the chamber. Thus, TPOS molecules (film forming gas 52) react with the TMA molecules (thin catalytic film 5A) covering the surface 4a of the photo resist film 4, and therefore oxygen atoms of the TPOS molecule and the TMA molecule bind to each other.

In this case, one TMA molecule reacts with one TPOS molecule, and then the catalytic action of methyl aluminum causes diffusion of other TPOS molecules toward methyl aluminum. Accordingly, oxygen bonding between the TPOS molecule and the methyl aluminum occurs sequentially, and thus a polymeric siloxane layer including a plurality of TPOS molecules each binding with methyl aluminum.

Further, interaction between each polymeric siloxane causes bridge bonds between adjacent polymeric siloxane molecules. Thus, a thin film (insulating hard mask 5) mainly including polymeric siloxane is formed over the photo resist film 4, as shown in FIG. 4C. Then, the film forming gas 52 (TPOS) is released from the chamber.

Then, when the catalytic gas (TMA) 51 is provided into the chamber again, TMA molecules selectively absorb onto a surface of the thin film (insulating hard mask 5) as shown in FIG. 4D, similarly to the case where TMA molecules have selectively absorbed onto the surface 4a of the photo resist film 4.

Therefore, the hard-mask formation process including the above first and second steps is repeated multiple times so that TMA molecules are deposited in a predetermined thickness. Thus, the insulating hard mask 5 having a predetermined thickness T can be selectively deposited on the surface 4a of the photo resist film 4, as shown in FIG. 4D.

FIGS. 4A to 4D illustrates flat upper surfaces 3a and 4a of the metal film 3 and the photo resist film 4, respectively, to demonstrate the difference between the attachment rate of the catalytic gas 51 to the metal film 3 and the attachment rate of the catalytic gas 51 to the photo resist film 4. If the catalytic gas is provided onto the side surfaces of the photo resist film 4, the catalytic thin film 5A is formed so as to cover the side surfaces of the photo resist film 4.

By the aforementioned hard-mask formation process, the insulating hard mask 5 made of an insulator is formed so as to cover the surface 4a of each photo resist film 4, as shown in FIG. 3B. If the hard-mask formation process is repeated a multiple number of times, the number of times the first and second steps are repeated is appropriately adjusted, and thereby the thickness T of the insulating hard mask 5 can easily be controlled.

The insulating hard mask 5 is deposited in substantially even thickness on the upper surface 4a and side surfaces of the photo resist film 4. Accordingly, a width of the insulating hard mask 5 at the time of the etching process is the pattern width W between each of the photo resist films 4 to which twice the thickness T of the insulating hard mask 5 (i.e., 2T) is added.

The thickness T required for the insulating hard mask 5 may be determined such that the insulating hard mask 5 has sufficient resistance at the time of the dry etching process after the hard-mask formation process. Accordingly, the thickness T may be preliminarily determined so that the pattern width W is determined based on the thickness T such that a value of the pattern width W to which twice the thickness T (i.e., 2T) is added becomes a desired wiring width.

As shown in FIG. 3B, the pattern interval (space portion) between adjacent photo resist films 4 can be narrower by twice the thickness T of the insulating hard mask 5 (i.e., by 2T). In other words, by use of this process, wiring patterning achieving a space portion narrower than a resolution limit of the photo resist film 4 is enabled.

In other words, when only the pattern made of the photo resist films is used as a mask as in the related arts, a space portion narrower than the resolution limit cannot be precisely formed, thereby causing short circuit of a wiring pattern. As also in the method disclosed in Japanese Patent Laid-Open Publication No. 2002-107957, a pattern width of the hard mask becomes the same as that of preliminarily formed photo resist films. Therefore, a space portion narrower than the resolution limit cannot be patterned either.

On the other hand, in the manufacturing method of the present invention, the photo resist films 4 are formed in the resist formation process so as to have a width which is substantially the same as the resolution limit. Then, the insulating hard mask 5 is formed in the hard-mask formation process. Consequently, a hard mask pattern achieving a further narrowed space portion between adjacent photo resist films 4 can be formed.

Accordingly, for example, if the metal wiring layer 3 including at least two independent wiring patterns is formed, an interval between adjacent wiring patterns includes a value smaller than the resolution limit for forming the pattern made of the photo resist films 4. Therefore, a wiring pattern, which is greatly miniaturized compared to the related art, can be easily formed.

Although the catalytic gas 51 used in the hard-mask formation process in the first embodiment is not specifically limited, a gas including aluminum is preferably used. TMA gas is more preferable as the gas including aluminum. TPOS gas is not specifically limited as the film forming gas 52. Other tris (tert-alkoxy) silanol gasses may be used as the film forming gas. For example, tris (tert-butoxy) silanol may be used for the film forming gas. Also in this case, a catalytic reaction with TMA molecules achieves selective formation of an insulator.

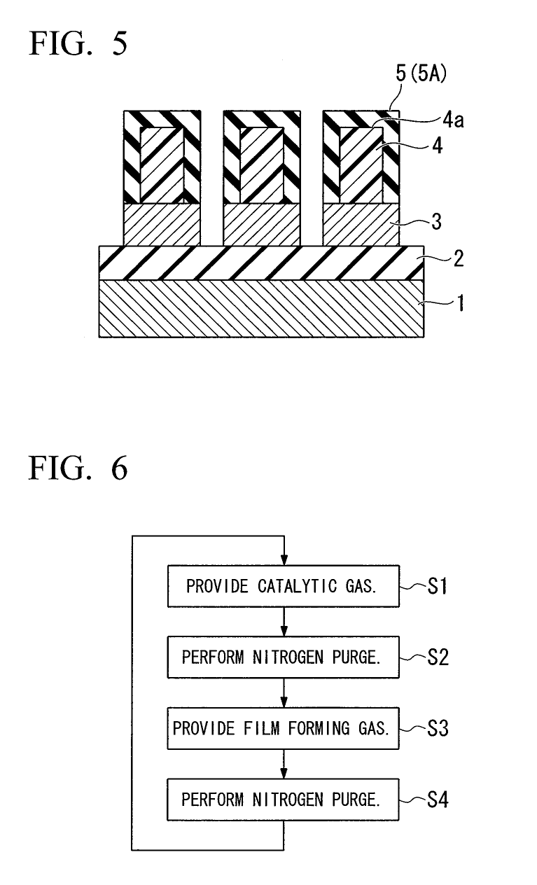

Then, in the etching process, the metal film 3A is dry etched using the insulating hard mask 5, as shown in FIG. 5. Specifically, the metal film 3A is anisotropically dry etched using, as a mask, the pattern made of the photo resist films 4 each covered by the insulating hard mask 5 so as to remove the metal film 3 exposed at the space portion between adjacent photo resist films 4.

Then, the insulating hard mask 5 is removed using a solution, such as dilute hydrofluoric acid. Then, the photo resist films 4 are removed by ashing, such as oxygen plasma ashing. Thus, the metal wiring layer 3 patterned as a desired wiring layer can be formed as shown in FIG. 1.

As explained above, the semiconductor device A can be manufactured. However, a method of manufacturing the semiconductor device of the first embodiment is not limited thereto. For example, a material forming each layer, a shape of each layer, a processing method, and the like can be appropriately changed.

According to the manufacturing method of the first embodiment, a variation in size of the pattern of the metal wiring layer 3 formed with use of the insulating hard mask 5 can be prevented. Additionally, the insulating hard mask 5 can be easily and precisely formed with a width required for achieving a desired etching resistance.

If the high-performance photo resist film 4 having a small resolution limit is used, easy formation of a miniaturized pattern of the metal wiring layer 3 and patterning of a wiring space narrower than the resolution limit is enabled. Therefore, high density allocation of the metal wiring layer 3 is enabled. Further, the number of processes required for manufacturing a semiconductor device can be reduced compared to the manufacturing methods in the related arts.

### Second Embodiment

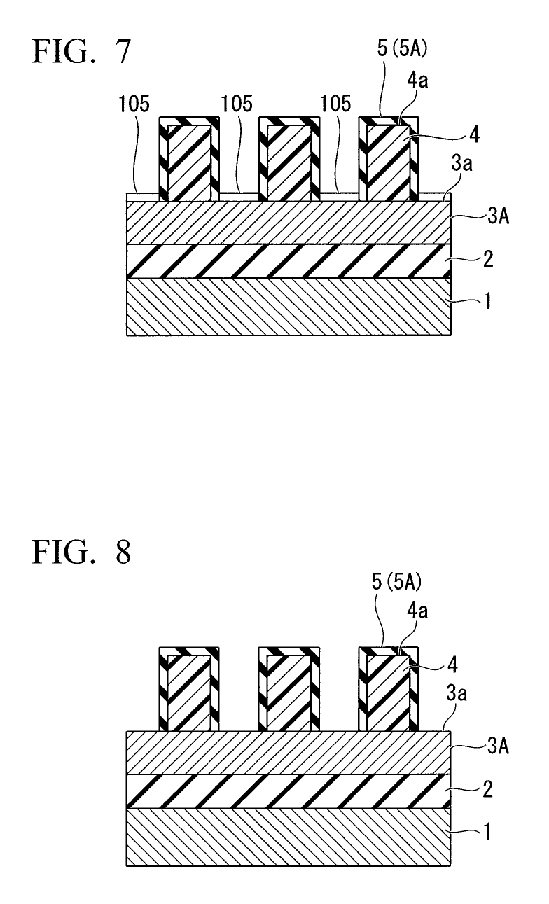

Hereinafter, a method of manufacturing a semiconductor device according to a second embodiment of the present invention is explained with reference to FIGS. 7 to 9. FIGS. 7 to 9 are cross-sectional views indicative of a process flow illustrating the method of the second embodiment.

A semiconductor device manufactured by the method of the second embodiment has the same structure as the semiconductor device A of the first embodiment shown in FIG. 1. Therefore, like reference numerals denote like elements, and explanations thereof are omitted here.

As shown in FIGS. 7 and 8, the method of the second embodiment differs from the method of the first embodiment in that a removal process of removing the thin catalytic film 5A remaining on the metal film 3A exposed between adjacent photo resist films 4 is included between the hard-mask formation process and the etching process.

After the hard-mask formation process, selectivity of attachment positions of an insulator forming the insulating hard mask 5 occasionally decreases depending on a condition of the surface of the metal film 3A to be patterned, a condition of formation of the insulating hard mask 5, and the like.

In such a case, if a cycle of the process (i.e., processes S1 to S4 shown in FIG. 6) is repeated one or more times, a thin film made of the insulator is occasionally formed not only on the photo resist film 4, but also on the metal film 3A. If the cycle of the film formation process is repeated in this state, another new thin film is deposited on the thin film deposited on the metal film 3A. For this reason, a pattern of the insulating hard mask 5 corresponding to the pattern made of the photo resist films 4 is occasionally difficult to form.

For example, the metal film 3A is formed over the semiconductor substrate 1 through the inter-layer insulating film 2, as shown in FIG. 7. Then, a pattern made of the photo resist films 4 is formed similarly to the first embodiment. Then, the film formation cycle (including the processes S1 to S4 shown in FIG. 6) is repeated once or more.

Consequently, the insulating hard mask 5 is formed on the surface 4a of each photo resist film 4. At the same time, the insulator is also deposited on the surface of the metal film 3, and thereby an insulating thin film 105 is formed. Even in this case, the insulating thin film 105 is much thinner than the photo resist film 4 since the attachment rate of the catalytic gas 51 onto the surface of the metal film 3A is smaller than that of the catalytic gas 51 onto the photo resist film 4.

In the second embodiment, the surface 3a of the metal film 3A is exposed by the removal process of removing the insulating thin film 105 on the meal film 3A by anisotropic dry etching or the like. In this case, a dry etching time is adjusted so as to have the insulating hard mask 5 on the surface 4a of each photo resist film 4 remain. Thus, the surface 3a of the metal film 3A is fully exposed, thereby recovering the selectivity at the time of the formation of the insulating hard mask 5.

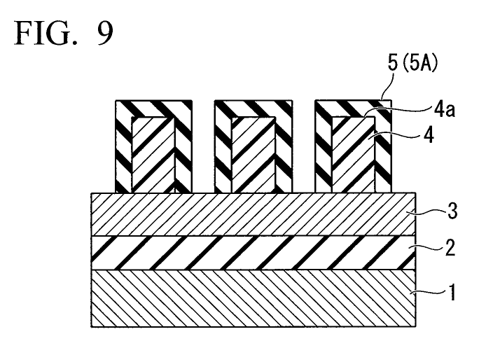

Then, the film forming cycle including the processes S1 to S4 shown in FIG. 6 is repeated. Thus, the insulating hard mask 5 covering the surface 4a of each photo resist film 4 with a desired width is formed as shown in FIG. 9. In this case, the removal process may be performed again to expose the surface 3a of the metal film 3A during the repetition of the above cycle according to need, so that the selectivity at the time of the formation of the insulating hard mask 5 is recovered.

According to the method of the second embodiment, even if the selectivity of deposition positions of the insulator forming the insulating hard mask 5 decreases, the selectivity can be easily recovered by the removal process. Accordingly, the insulating hard mask 5 can be formed with the recovered selectivity.

Although the total number of processes of the second embodiment increases compared to the method of the first embodiment due to the addition of the removal process, a variation in size of the pattern of the metal wiring layer 3 formed with use of the insulating hard mask 5 can be prevented. Additionally, the insulating hard mask 5 can be easily and precisely formed with a width required for achieving a desired etching resistance. Further, similar to the first embodiment, patterning of wirings including a space portion narrower than the resolution limit of the photo resist film 4 is enabled.

As explained above, according to the methods of the embodiments of the present invention, a generally-used photo resist film can be used without any limit in the processes of manufacturing a semiconductor device since it is not necessary to include silicon or the like into the photo resist film 4. Accordingly, a high-performance photo resist film having higher resolution is used, and thereby the metal wiring layer 3 including a more miniaturized pattern can be formed.

Additionally, the thickness of the insulating hard mask 5 selectively formed on the surface of the photo resist film 4 is easily controlled, and thereby the insulating hard mask 5 can be evenly formed regardless of formation positions. Accordingly, a variation in size of a pattern of the metal wiring layer 3, which is caused by the insulating hard mask 5, can be prevented in the etching process. Further, the insulating hard mask 5 having a thickness achieving a desired resistance required for etching the pattern of the metal wiring layer 3 can be easily formed.

Moreover, the insulating hard mask 5 is selectively formed corresponding to the pattern made of the photo resist films 4. Therefore, a process of transferring the pattern made of the photo resist films by etching, which is required for forming a hard mask in the related arts, is unnecessary. Accordingly, the number of processes required for manufacturing a semiconductor device is not increased, thereby enabling an increase in the manufacturing efficiency.

### Example

Hereinafter, an example of the present invention is explained in detail with reference to FIGS. 1 to 6. However, the present invention is not limited to the following example. In the example, the semiconductor device A shown in FIG. 1 was manufactured based on the method of the first embodiment.

As shown in FIG. 2, a silicon oxide (SiO₂) film was deposited by CVD over the semiconductor substrate 1 made of silicon to form the inter-layer insulating film 2. Then, a tungsten nitride (WN) film having a thickness of 10 nm and a tungsten (W) film having a thickness of 40 nm were sequentially deposited over the inter-layer insulating film 2 to form the metal film 3A.

Then, in the resist formation process, a pattern made of the photo resist films 4 is formed on the metal film 3A using a chemically amplified photo resist, which is photosensitive to an ArF excimer laser (having a wavelength of 193 nm).

Then, in the hard-mask formation process, the processes S1 to S4 shown in FIG. 6 are repeated to selectively deposit an insulator on the surface 4a of each photo resist film 4.

Specifically, as the process S1 shown in FIG. 6, a wafer including the semiconductor substrate 1, and the inter-layer insulating film 2 and the metal film 3A over the semiconductor device 1 was provided in a film forming chamber. Then, 1 mol of the TMA gas was provided as the catalytic gas 51 while the temperature of the semiconductor substrate 1 was kept at 100° C. and a pressure inside the chamber was kept at 5 Torr. Thus, the thin catalytic film 5A made of methyl aluminum was deposited on the surface 4a of each photo resist film 4.

Then, as the process S2, the TMA gas (catalytic gas 51) was released from the chamber using a vacuum pump. Then, a nitride gas was provided to replace the air in the chamber.

Then, as the process S3, 100 μmol of the TPOS gas was provided as the film forming gas 52 while the temperature of the semiconductor substrate 1 was kept at 100° C. and a pressure inside the chamber was kept at 2 Torr. Thus, a catalytic reaction of TPOS molecules with the thin catalytic film 5A made of methyl aluminum occurred, and a hard mask was formed.

Then, as the process S4, the TPOS gas (film forming gas 52) was released from the chamber using a vacuum pump. Then, a nitride gas was provided to replace the air in the chamber.

By the hard-mask formation process including the above processes S1 to S4, the insulating hard mask 5, which is made of the insulator and has a thickness of approximately 10 nm, could be selectively formed on the photo resist film 4.

Further, the cycle including the processes S1 to S4 shown in FIG. 6 is repeatedly carried out, and thereby the thickness of the insulating hard mask 5 on the surface 4a of the photo resist film 4 could be increased up to approximately 50 nm.

In this case, the thickness of the insulating hard mask formed by one cycle (i.e., the processes S1 to S4) varied depending on the number of times the cycle was repeated. This is probably because the film forming reaction progressed differently depending on the state of the underlying surface on which the insulating material was deposited.

Then, in the etching process, anisotropic dry etching with an etching gas containing SF₆ was carried out using the insulating hard mask 5 formed in the hard-mask formation process to pattern the metal film 3A, as shown in FIG. 5.

Then, the insulating hard mask 5 was removed by wet etching with dilute hydrofluoric acid. Then, the photo resist film 4 was removed by plasma ashing with an oxygen gas. Thus, the metal wiring layer 3 including a desired wiring pattern was formed as shown in FIG. 1.

It was confirmed in the example that the thickness of the insulator (insulating hard mask) to be deposited can be increased according to need by increasing the number of times the film forming cycle was carried out.

Additionally, it was confirmed in this case that the thickens of the insulating hard mask deposited by one film forming cycle can be controlled in the range of 1 to 100 nm by adjusting film forming conditions.

Accordingly, it was confirmed that an insulating hard mask having a desired thickness can be obtained by appropriately selecting a thickness of the insulator (insulating hard mask) to be deposited by one film forming cycle and the number of times the film forming cycle is carried out.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A method of manufacturing a semiconductor device, comprising:
forming a conductive film over a semiconductor substrate;
forming first and second photo resist patterns on the conductive film, a space being located between the first and second photo resist patterns;
forming an insulating mask by using catalytic reaction, the insulating mask covering surfaces of the first and second photo resist patterns to protect the surfaces of the first and second photo resist patterns; and
etching a part of the conductive film by using the insulating mask on the first and second photo resist patterns as an etching mask.

2. The method according to claim 1, wherein the conductive film is a metal film.

3. The method according to claim 1, wherein the space after forming the insulating mask is smaller in size than a resolution limit for forming the first and second photo resist patterns.

4. The method according to claim 1, wherein forming the insulating mask comprises selectively depositing an insulator onto the surfaces of the first and second photo resist patterns.

5. The method according to claim 4, wherein selectively depositing the insulator comprises:
providing a first gas over the first and second photo resist patterns, a catalytic material being included in the first gas; and
providing a second gas so that the second gas reacts with the catalytic material attached onto the first and second photo resist patterns.

6. The method according to claim 5, wherein an attachment rate of the catalytic material to the first and second photo resist patterns is greater than that of the catalytic material to the conductive film.

7. The method according to claim 5, further comprising:
removing the insulator deposited on the conductive film exposed through the space before etching a part of the conductive film.

8. The method according to claim 1, wherein the first gas is a catalytic gas including aluminum.

9. The method according to claim 1, wherein the second gas is tris (tert-alkoxy) silanol.

10. The method according to claim 9, wherein the tris (tert-alkoxy) silanol is tris (tert-pentoxy) silanol or tris (tert-butoxy) silanol.

11. The method according to claim 1, wherein
the first gas is tri-methyl aluminum, and
the second gas is tris (tert-pentoxy) silanol.

12. The method according to claim 5, wherein a set of providing the first gas and providing the second gas is repeatedly carried out until the insulating mask has a predetermined thickness.

13. The method according to claim 5, wherein a thickness of the insulating mask formed by a set of providing the first gas and providing the second gas is in the range of 1 nm to 100 nm.

14. The method according to claim 1, wherein the insulating mask comprises a polymeric siloxane film formed by a reaction between the second gas and the catalytic material.

15. The method according to claim 1, further comprising:
removing the insulating mask after etching a part of the conductive film; and
removing the first and second photo resist patterns by ashing to obtain first and second wiring films over the semiconductor substrate.

16. A method of manufacturing a semiconductor device, comprising:
forming a conductive film over a semiconductor substrate;
forming first and second photo resist patterns over the conductive film;
providing a first gas including a catalytic material over the semiconductor substrate, an attachment rate of the catalytic material to the first and second photo resist patterns being greater than that of the catalytic material to the conductive film;
providing a second gas so that the second gas reacts with the catalytic material attached onto the first and second photo resist patterns to form an insulating hard mask covering surfaces of the first and second photo resist patterns; and
etching a part of the conductive film by using the insulating mask on the first and second photo resist patterns as an etching mask.

17. The method according to claim 16, wherein the second gas includes silanol, and the insulating hard mask comprises a polymeric siloxane film.

18. The method according to claim 17, wherein the catalytic material includes aluminum.

19. A method of manufacturing a semiconductor device, comprising:
forming a conductive film over a semiconductor substrate;
forming first and second photo resist patterns on the conductive film;
forming an insulating mask by using catalytic reaction, the insulating mask covering surfaces of the first and second photo resist patterns to reduce a horizontal size of the conductive film exposed between the first and second photo resist patterns, the horizontal size being smaller than a resolution limit for forming the first and second photo resist patterns; and
etching a part of the conductive film by using the insulating mask on the first and second photo resist patterns as an etching mask.

20. The method according to claim 19, wherein the catalytic reaction is performed by using a first gas and a second gas, wherein the first gas includes aluminum, and the second gas includes tris (tert-alkoxy) silanol.
